(19) United States
(12) Patent Application Publication
(10) Pub. No.: US 2026/0100690 A1
(43) Pub. Date: Apr. 9, 2026

(54) ACOUSTIC WAVE DEVICE AND FABRICATION METHOD THEREOF

(71) Applicant: RichWave Technology Corp., Taipei City (TW)

(72) Inventor: Hao-Min Huang, Taipei City (TW)

(73) Assignee: RichWave Technology Corp., Taipei City (TW)

(21) Appl. No.: 18/929,549

(22) Filed: Oct. 28, 2024

(30) Foreign Application Priority Data
Oct. 9, 2024 (TW) 113138432

(51) Int. Cl. H03H 9/02; H03H 3/08; H03H 9/05; H03H 9/10

(52) U.S. Cl. CPC H03H 9/02992; H03H 3/08; H03H 9/059; H03H 9/1085

(57) ABSTRACT

An acoustic wave device includes a piezoelectric substrate, a plurality of transducers, and a film. The piezoelectric substrate includes a recess, and the plurality of transducers are positioned in the recess. At least one of the plurality of transducers includes a first bus bar disposed in parallel to a first direction, a plurality of first electrodes extended in parallel to a second direction from the first bus bar, a second bus bar disposed in parallel to the first direction, and a plurality of second electrodes extended in parallel to the second direction from the second bus bar. The film covers the recess of the piezoelectric substrate.

### TECHNICAL FIELD

The invention relates to acoustic wave device, and in particular, to a surface acoustic wave device and a fabrication method thereof.

### BACKGROUND

Surface acoustic wave (SAW) devices are used to convert and transmit electrical signals and acoustic signals, and are widely used in many fields. A SAW device including an interdigital transducer (IDT) and a piezoelectric substrate may be configured to convert electrical signals and acoustic signals, for example, for filtering signals. For example, SAW devices may be used as SAW filters. SAW filters may filter out a noise and retain signals in desired frequency bands. SAW filters may exhibit advantages such as low transmission loss, strong resistance to electromagnetic interference, size compactness, etc. Therefore, SAW filters are widely used in various communication products. Furthermore, SAW devices may also be used as resonators, transformers, sensors, etc.

In related art, the IDT may be disposed on a surface of a substrate. For example, in order to isolate various solutions used during the fabrication process, which may adversely corrode the IDT, protective walls and/or top covers may be provided around and above the IDT, so as to form a cavity to accommodate the IDT. However, protective walls and top covers may increase the size and the cost of the SAW device, and may not be conducive to circuit miniaturization.

### SUMMARY

According to an embodiment of the invention, an acoustic wave device includes a piezoelectric substrate, a plurality of transducers, and a film. The piezoelectric substrate includes a recess, and the plurality of transducers are positioned in the recess. At least one of the plurality of transducers includes a first bus bar disposed in parallel to a first direction, a plurality of first electrodes extended in parallel to a second direction from the first bus bar, a second bus bar disposed in parallel to the first direction, and a plurality of second electrodes extended in parallel to the second direction from the second bus bar. The film covers the recess of the piezoelectric substrate.

According to another embodiment of the invention, a fabrication method of an acoustic wave device includes providing a piezoelectric substrate, forming a recess in the piezoelectric substrate, forming a plurality of transducers in the recess, and forming a film above the recess of the piezoelectric substrate.

### BRIEF DESCRIPTION OF THE DRAWINGS

FIG. 1 is a schematic cross-sectional view of an acoustic wave device according to an embodiment of the present invention.

FIG. 2A is a schematic top view of a part of the acoustic wave device according to an embodiment of the present invention.

FIG. 2B is a schematic top view of a part of the acoustic wave device according to an embodiment of the present invention.

FIG. 3 is a schematic flow chart of a fabrication method of an acoustic wave device according to an embodiment of the present invention.

FIGS. 4 to 8 are schematic diagrams of steps of a fabrication method of an acoustic wave device according to an embodiment of the present invention.

### DETAILED DESCRIPTION

Below, exemplary embodiments may be described in detail with reference to accompanying drawings so as to be easily realized by a person having ordinary knowledge in the art. The inventive concept may be embodied in various forms without being limited to the exemplary embodiments set forth herein. Descriptions of well-known parts may be omitted for clarity, and like reference numerals may refer to like elements throughout.

It should be noted that, for the sake of clarity and simplicity, the drawings in the present invention may only depict a part of the electronic device, and the specific elements in the drawings may not be drawn to scale. Additionally, the quantity and size of the elements in the drawings are merely illustrative and are not intended to limit the scope of the present invention.

In the following specification and claims, terms “comprising,” “including,” and “having” are open-ended terms, and therefore should be interpreted as “including but not limited to.” Thus, when the description of the present invention uses the terms “comprising,” “including,” and/or “having,” it specifies the presence of corresponding features, regions, steps, operations, and/or components, but does not exclude the presence of other features, regions, steps, operations, and/or components.

Directional terms mentioned herein, such as “on,” “above,” “inner,” “outer,” “upper,” “lower,” “front,” “rear,” “left,” “right,” etc., may merely references to the directions in the drawings. Therefore, the directional terms are used for explanation and not to limit the present invention. In the drawings, the depicted methods, structures, and/or materials are typical features used in specific embodiments. However, these drawings should not be construed as defining or limiting the scope or nature of the embodiments covered. For example, for clarity, the relative sizes, thicknesses, and positions of various layers, regions, and/or structures may be reduced or enlarged.

It should be noted that the following embodiments may be replaced, reorganized, and combined with features from different embodiments without departing from the spirit of the present invention to complete other embodiments. The features of the embodiments may be mixed and matched as long as they do not contradict or conflict with the spirit of the invention.

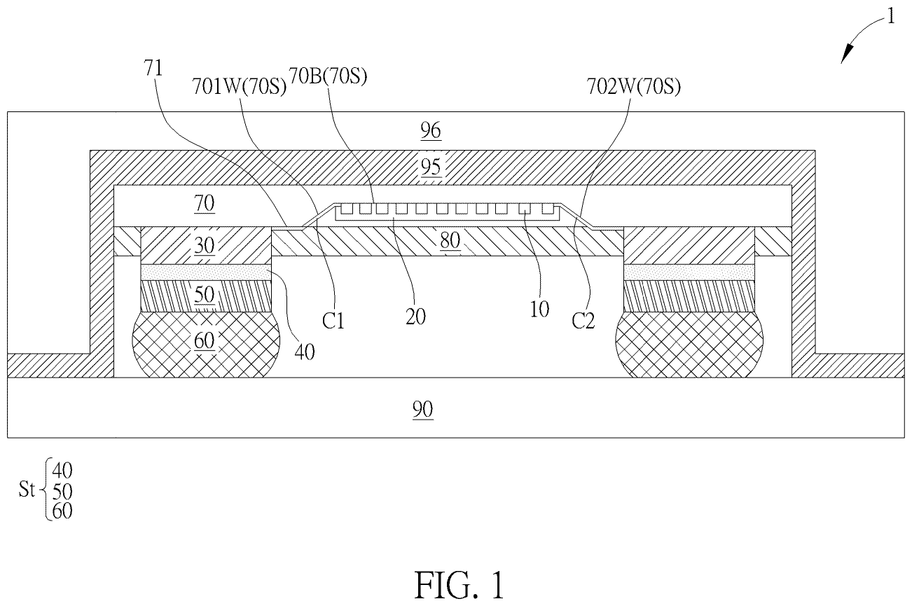

FIG. 1 is a schematic cross-sectional view of an acoustic wave device 1 according to an embodiment of the present invention. The acoustic wave device 1 may be, for example, a surface acoustic wave (SAW) device. In some embodiments, the acoustic wave device 1 may receive a radio frequency signal from an antenna, convert the radio frequency signal into an acoustic wave, filter the acoustic wave to generate a filtered signal, and output the filtered signal for subsequent use. The radio frequency signal and the filtered signal may be electrical signals. The use of the acoustic wave device 1 is illustrated here by examples, but the present invention is not limited thereto. In other embodiments, the acoustic wave device 1 may also be used for other purposes. As shown in FIG. 1, in some embodiments, the acoustic wave device 1 may include a piezoelectric substrate 70, at least one transducer 10, and a film 80. The piezoelectric substrate 70 may include a recess 70S. The at least one transducer 10 may be disposed in the recess 70S. The film 80 may at least cover the recess 70S of the piezoelectric substrate 70.

In some embodiments, the piezoelectric substrate 70 may include a substrate surface 71, and the recess 70S may be recessed from the substrate surface 71. Specifically, the recess 70S may include a bottom 70B and at least one side wall surrounding the bottom 70B, such as side walls 701W and 702W. The at least one side wall may be wrapped around to form a rectangle or another polygonal shape. An obtuse angle may be formed between the sidewall 701W and the bottom 70B, or another obtuse angle may be formed between the sidewall 702W and the bottom 70B, which may be explained further below.

The piezoelectric substrate 70 may be a single-layer structure and may include at least one of the following piezoelectric materials: zinc oxide (ZnO), aluminum nitride (AlN), lithium tantalate (LiTaO3, LT), lithium niobate (LN), quartz (QZ), perovskite type lead titanate (PTO), lead zirconate titanate (PZT) or their combinations. In other embodiments, the piezoelectric substrate 70 may be a multi-layer structure and may include a base substrate and a piezoelectric layer disposed thereon. The base substrate may include silicon, and the piezoelectric layer may include at least one of the piezoelectric materials as described above. In yet another embodiment, the piezoelectric material may also include other types of piezoelectric single crystals, piezoelectric polycrystals (including piezoelectric ceramics), piezoelectric polymers, and/or piezoelectric composite materials.

In some embodiments, at least one transducer 10 may be disposed in the recess 70S. At least one transducer 10 may include transducers 101 to 10N, and N is a positive integer greater than 1. Each transducer may be an interdigital transducer (IDT). The transducers 101 to 10N may all be disposed in the same recess 70S, thereby reducing the circuit area. For example, in case of N=8, the eight transducers 101 to 108 may all be disposed in the same recess 70S.

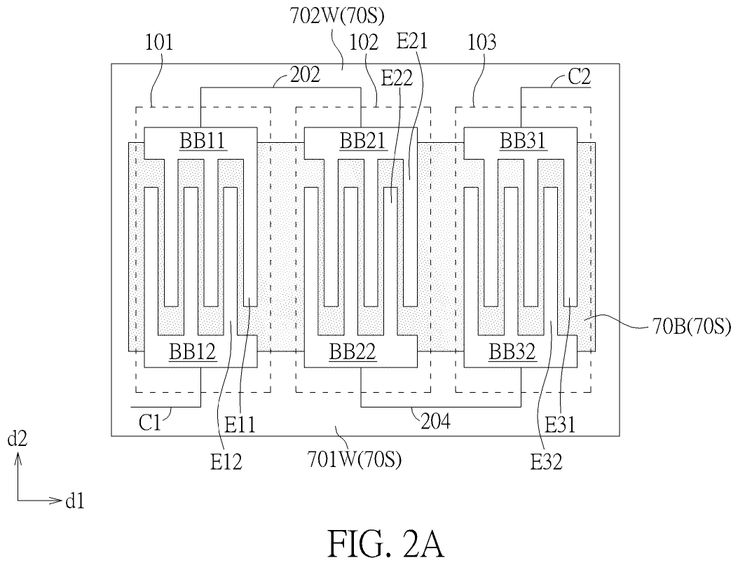

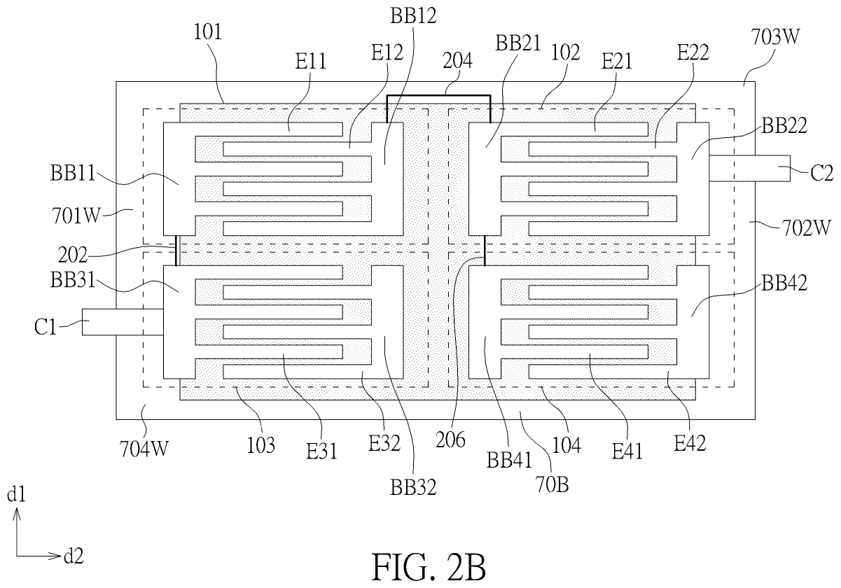

FIG. 2A and FIG. 2B are schematic top views of a part of the acoustic wave device according to an embodiment of the present invention. For example, referring to FIGS. 1 and 2A, the acoustic wave device 1 may include transducers 101 to 103 positioned in the recess 70S (the recess 70S shown as the sidewalls 701W, 702W, and the bottom 70B in FIG. 2A). In the embodiment shown in FIG. 2A, the transducer 101 may be electrically connected to the transducer 102, and the transducer 102 may be electrically connected to the transducer 103 via a signal trace 204. In other words, the transducers 101 to 103 may be coupled in series. However, the present invention is not limited thereto. For example, in other embodiments, the transducer 101 and the transducer 102 may be electrically disconnected, and/or the transducer 102 and the transducer 103 may be electrically disconnected.

In some embodiments, taking the transducer 101 as an example, the transducer 101 may include a first bus bar BB11, which may be disposed in parallel to a first direction d1. The plurality of first electrodes E11 may be extended from the first bus bar BB11 and extended in parallel to a second direction d2. The second bus bar BB12 may be disposed in parallel to the first direction d1. The plurality of second electrodes E12 may be extended in parallel to the second direction d2 from the second bus bar BB12. The plurality of first electrodes E11 and/or the plurality of second electrodes E12 may be finger electrodes. When viewed along the first direction d1, the plurality of first electrodes E11 and the plurality of second electrodes E12 may be alternately arranged and overlap each other. Furthermore, the region where the first electrodes E11 and the second electrodes E12 overlap may be defined as an effective area of the transducer 101. In the embodiment of FIG. 2A, the first direction d1 may be perpendicular to the second direction d2, but the present invention is not limited thereto. In other embodiments, the first direction d1 may not be perpendicular to the second direction d2. For example, the angle between the first direction d1 and the second direction d2 may be an acute angle.

As shown in FIG. 2A, the first electrodes E11 and the second electrodes E12 of the transducer 101 may be disposed on the bottom 70B of the recess 70S. The first bus bar BB11 may be partially disposed on the side wall 702W of the recess 70S. Specifically, a portion of the first bus bar BB11 may be disposed on the bottom 70B of the recess 70S, and another portion may be disposed on the side wall 702W of the recess 70S. Similarly, the second bus bar BB12 may be partially disposed on the side wall 701W of the recess 70S. Specifically, a portion of the second bus bar BB12 may be disposed on the bottom 70B of the recess 70S, and another portion may be disposed on the side wall 701W of the recess 70S.

In this embodiment, the portion of the bus bar disposed on the side wall may function as a frame structure for the transducer 101, which may be favorable with respect to suppressing energy leakage. Specifically, the frame structure may be used to substantially concentrate the energy of the acoustic signal in the effective area of the transducer 101, thereby suppressing or eliminating energy leakage caused by spurious modes.

In other embodiments, the first bus bar BB11 and/or the second bus bar BB12 may not be disposed on the side wall 702W or 701W. That is, the first bus bar BB11 and/or the second bus bar BB12, along with the first electrode E11 and the second electrode E12, may be disposed on the bottom 70B.

Similarly, the transducer 102 may include a first bus bar BB21, a plurality of first electrodes E21, a second bus bar BB22, and a plurality of second electrodes E22. The configuration of the transducer 102 may be similar to the transducer 101 and description may not be repeated. It should be noted that, in the embodiment of FIG. 2A, the transducer 102 is arranged in parallel to the transducer 101, but the present invention is not limited thereto. In other embodiments, the first bus bar BB21 and/or the second bus bar BB22 of the transducer 102 may be disposed in parallel to a third direction d3, and the third direction d3 may not be parallel to the first direction d1 shown in FIG. 2A. The first electrode E21 and/or the second electrode E22 of the transducer 102 may be disposed in parallel to a fourth direction d4, and the fourth direction d4 may not be parallel to the second direction d2 shown in FIG. 2A. In some embodiments, the configuration of the transducer 103 may be similar to the transducer 102 and description may not be repeated.

A variety of conductive materials may be used for a bus bar, an electrode, and/or a connection part. For example, example conductive materials may include molybdenum (Mo), copper (Cu), aluminum (Al), gold (Au), platinum (Pt), tungsten (W), other suitable metals, alloys, and combinations thereof.

Furthermore, the acoustic wave device 1 may further include a first connection part C1 and a second connection part C2. The first connection part C1 may be coupled to the transducer 101 and the second connection part C2 may be coupled to the transducer 103. Specifically, the first connection part C1 may be coupled to the second bus bar BB12 of the transducer 101, and the transducer 101 may be electrically connected to other components via the first connection part C1. For example, via the first connection part C1, the transducer 101 may be electrically connected to an inductor, a capacitor, a connection port, etc. Similarly, the second connection part C2 may be coupled to the first bus bar BB31 of the transducer 101, and the transducer 103 may be electrically connected to other components via the second connection part C2. The acoustic wave device 1 may receive an input signal via the first connection part C1 and provide a filtered signal via the second connection part C2.

As shown in FIG. 2A, the first connection part C1 may be disposed on the side wall 701W of the recess 70S, and the second connection part C2 may be disposed on the side wall 702W. However, the present invention is not limited thereto. In other embodiments, a first portion of the first connection part C1 may be disposed on the bottom 70B of the recess 70S, a second portion may be disposed on the side wall 701W of the recess 70S, and a third portion may be disposed on the substrate surface 71. Similarly, a first portion of the second connection part C2 may be disposed on the bottom 70B of the recess 70S, a second portion may be disposed on the side wall 702W of the recess 70S, and a third portion may be disposed on the substrate surface 71. In this embodiment, an obtuse angle may be formed between the side wall 701W and the bottom 70B, so that the connection between the side wall 701W and the bottom 70B may be smoother. Similarly, another obtuse angle may be formed between the side walls 702W and the bottom 70B, so that the connection between the side wall 702W and the bottom 70B may be smoother. Stress concentration may be alleviated accordingly. Therefore, the connection parts C1 and C2 may be formed on the side walls 701W and 702W in a relatively conformal manner. The formed connection parts C1 and C2 may have lower internal stress and are less likely to break, so as to improve the stability and durability of the overall structure and thereby improve the yield.

Please refer to FIG. 1 and FIG. 2A, the film 80 may be disposed on the substrate surface 71 of the piezoelectric substrate 70, so as to cover the recess 70S of the piezoelectric substrate 70, thereby defining a cavity. The cavity may be used to accommodate transducers 101 to 103, for example. Since the transducers 101 to 103 may be disposed in the cavity, the transducers 101 to 103 may be substantially protected from contamination or extrusion, thereby enhancing the performance of the acoustic wave device 1.

The film 80 may include a photosensitive polymer dry film, such as a polyimide film or an epoxy film.

In some embodiments, the thickness of the piezoelectric substrate 70 may be about 200 micrometers (μm), and the depth of the recess 70S from the substrate surface 71 may be between 20 μm and 30 μm. The thickness of an electrode of the transducer 101 may be between 0.2 μm and 1 μm (that is, between 2000 Å and 10000 Å), and the thickness of the film 80 may be between 40 μm and 50 μm.

In some embodiments, as shown in FIG. 2B, the acoustic wave device 1 may include the transducers 101 to 104, which may be disposed in the recess 70S (the recess 70S shown as the side walls 701W, 702W, 703W, 704W, and the bottom 70B in FIG. 2B). The configuration of the transducers 101-104 may be similar to the transducers 101-103 of FIG. 2A.

In the embodiment shown in FIG. 2B, the transducers 101 and 102 may be coupled in series between the first connection part C1 and the second connection part C2, the transducer 103 may be coupled to the first connection part C1, and the transducer 104 can be coupled to the transducer 102. Specifically, the first bus bar BB11 of the transducer 101 may be electrically connected to the first bus bar BB31 of the transducer 103 via a signal trace 202, and the first bus bar BB31 of the transducer 103 may be electrically connected to the first connection part C1. The second bus bar BB12 of the transducer 101 may be electrically connected to the first bus bar BB21 of the transducer 102 via the signal trace 204, and the second bus bar BB22 of the transducer 102 may be electrically connected to the second connection part C2. The first bus bar BB21 of the transducer 102 may be electrically connected to the first bus bar BB41 of the transducer 104 via the signal trace 206.

Furthermore, the first bus bar BB31 of the transducer 103 may be electrically connected to the first connection part C1, and the second bus bar BB32 of the transducer 103 may be further electrically connected to other connections, such as ground. The first bus bar BB41 of the transducer 104 may be electrically connected to the first bus bar BB21 of the transducer 102, and the second bus bar BB42 of the transducer 104 may be further electrically connected to other connections, such as ground. In some embodiments, the transducers 101 and 102 may be series-connected transducers, and the transducers 103 and 104 may be parallel-connected transducers, or shunt-connected transducers. The acoustic wave device 1 may receive a radio frequency input signal via the first connection part C1 and provide a filtered signal via the second connection part C2.

As shown in FIG. 2B, the first connection part C1 may be disposed on the side wall 701W of the recess 70S, and the second connection part C2 may be disposed on the side wall 702W. A Portion of the bus bar BB11 and a portion of the bus bar BB31 may be disposed on the bottom 70B of the recess 70S. Another portion of the bus bar BB11 and another portion of the bus bar BB31 may be disposed on the side wall 701W. Bus bars BB12, BB32, BB21 and BB41 may be provided on the bottom 70B. A portion of the bus bar BB22 and a portion of the bus bar BB42 may be disposed on the bottom 70B of the recess 70S. Another portion of the bus bar BB22 and another portion of the bus bar BB42 may be disposed on the side wall 702W.

It should be noted that in the embodiment of FIG. 2B, the electrodes E11, E12, E21, E22, E31, E32, E41, and E42 of the transducers 101 to 104 are arranged in parallel. However, the present invention is not limited thereto. In other embodiments not shown, one or more of the electrodes may be non-parallel.

In some embodiments, referring to FIG. 1, the acoustic wave device 1 may further include a passivation layer 20 disposed in the recess 70S and covering the transducer 10, such as covering the bus bars and electrodes of the transducer 10. In this embodiment, the cavity may not be filled with the passivation layer 20. That is to say, the cavity may not be completely filled with the passivation layer 20. In other embodiments, the cavity may be filled with the passivation layer 20. That is to say, the cavity may be completely filled with the passivation layer 20. The material for the passivation layer 20 may include silicon dioxide and silicon nitride, and the thickness of the passivation layer 20 may be 250 angstroms (Å). In some embodiments, the passivation layer 20 may be omitted.

In some embodiments, the acoustic wave device 1 may further include a soldering pad 30 disposed on the substrate surface 71 of the piezoelectric substrate 70. The soldering pad 30 may be electrically connected to the transducer 10 via the first connection part C1 or the second connection part C2. For example, in FIG. 2A, the transducer 101 may be coupled to the soldering pad 30 (not shown in FIG. 2A) via the first connection part C1. Furthermore, the transducer 103 may further be coupled to another soldering pad via the second connection part C2.

In some embodiments, the acoustic wave device 1 may further include a stack St disposed on the soldering pad 30. The stack St may be conductive or non-conductive, so as to provide electrical connection and/or support. In some embodiments, a conductive stack St may be used to achieve an electrical connection between the transducer 10 and an external circuit, and may also provide support between the piezoelectric substrate 70 and a carrier 90. In other embodiments, a non-conductive stack St may provide support between the piezoelectric substrate 70 and a carrier 90. In this embodiment, the stack St may include a seed layer 40, a metal layer 50, and a solder ball 60 stacked in sequence. In some embodiments, the seed layer 40 may be omitted and thus the metal layer 50 may be formed directly on the soldering pad 30.

The material for the soldering pad 30 may include molybdenum (Mo), copper (Cu), aluminum (Al), gold (Au), platinum (Pt), tungsten (W), nickel (Ni), silver (Ag), tantalum (Ta) and other materials or combinations thereof. The material for the seed layer 40 may include titanium (Ti), nickel (Ni) or alloys thereof. The material for the metal layer 50 may include copper (Cu), aluminum (Al), nickel (Ni), tin (Sn), silver (Ag) or alloys thereof. The material for the solder ball 60 may include tin(Sn) or lead (Pb). In some embodiments, the thickness of the metal layer 50 may be greater than the thickness of the seed layer 40. In some embodiments, the metal layer 50 may be referred to as under-bump metallization (UBM).

According to at least one embodiment of the present invention, a plurality of transducers of an acoustic wave device may be disposed in a recess of the piezoelectric substrate, and a film may be formed on the recess. At least one side wall of the recess may provide appropriate structural support. Therefore, the risk of contamination or extrusion may be reduced, and the yield may thereby be increased. In at least one embodiment of the present invention, conventional protective walls and/or roofs on the surface of the piezoelectric substrate may be omitted.

In some embodiments, the acoustic wave device 1 may further include a carrier 90, a protective film 95, and a seal 96 for packaging, which may be further described below.

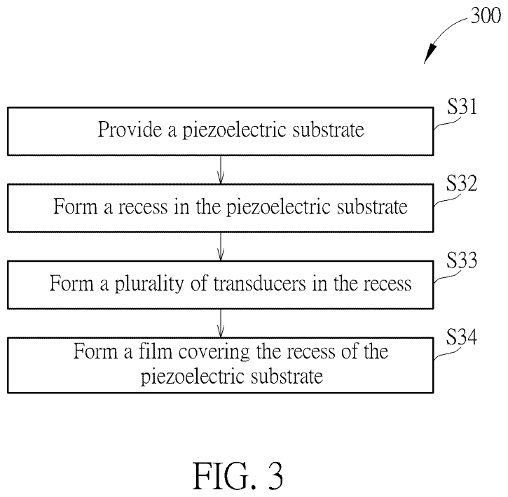

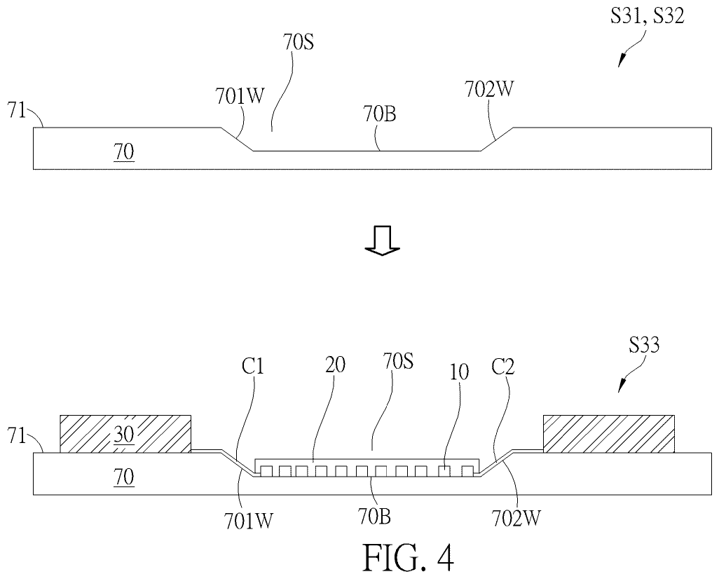

FIG. 3 is a schematic flow chart of a fabrication method 300 of an acoustic wave device according to an embodiment of the present invention. FIGS. 4 to 8 are schematic diagrams of steps of the fabrication method 300 of an acoustic wave device according to an embodiment of the present invention. The fabrication method 300 may include steps S31 to S34. Any reasonable step change or adjustment is within the scope of the disclosure. Steps S31 to S34 are explained as follows:
Step S31: Provide a piezoelectric substrate 70;
Step S32: Form a recess 70S on the piezoelectric substrate 70;
Step S33: Form a plurality of transducers 10 in the recess 70S;
Step S34: Form a film 80 above the recess 70S of the piezoelectric substrate 70.

The fabrication method 300 is further described below with reference to FIGS. 4 to 8.

As shown in FIG. 4, in Step S31, the piezoelectric substrate 70 is provided. In Step S32, The piezoelectric substrate 70 is etched to form a recess 70S, which is recessed from a substrate surface 71. Etching may include a dry etching process and a wet etching process. The recess 70S may include a bottom 70B and at least one side wall surrounding the bottom 70B, such as side walls 701W, 702W. In step S33, a plurality of transducers 10 may be formed in the recess 70S.

In some embodiments, the fabrication method 300 may further include forming a first connection part C1 and a second connection part C2. For example, the first connection part C1 and the second connection part C2 may be coupled to different ones of the plurality of transducers 10. For example, the first connection part C1 may be formed at least on the side wall 701W of the recess 70s. Specifically, a first portion of the first connection part C1 may be disposed on the bottom 70B of the recess 70S, a second portion may be disposed on the side wall 701W of the recess 70S, and a third portion may be disposed on the substrate surface 71. Similarly, the second connection part C2 may be formed at least on the side wall 702W of the recess 70s. Specifically, a first portion of the second connection part C2 may be disposed on the bottom 70B of the recess 70S, a second portion may be disposed on the side wall 702W of the recess 70S, and a third portion may be disposed on the substrate surface 71.

In some embodiments, the fabrication method 300 may further include forming a passivation layer 20. The passivation layer 20 may be positioned in the recess 70S and may cover the plurality of transducers 10. The passivation layer 20 may be used to protect the transducer 10 from particles and solutions used during the fabrication process.

In some embodiments, the fabrication method 300 may further include forming a soldering pad 30 on the substrate surface 71 of the piezoelectric substrate 70. The soldering pad 30 may be electrically connected to, for example, the first connection part C1 and further to the plurality of transducers 10. In other embodiments, another soldering pad electrically connected to the second connection part C2 may be additionally or alternatively formed.

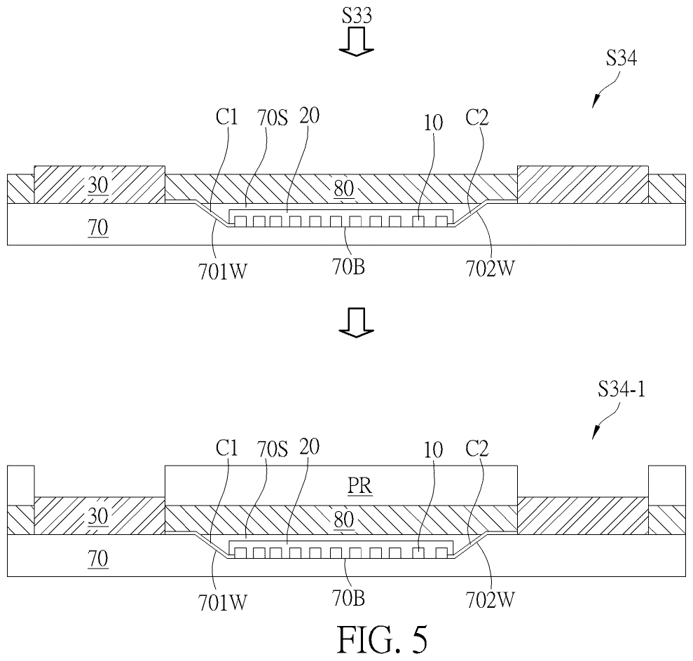

As shown in FIG. 5, in Step S34, the film 80 may be formed above the recess 70S of the piezoelectric substrate 70. In some embodiments, the step of forming the film 80 may include forming a dry film on the piezoelectric substrate 70 and patterning the dry film to form a patterned dry film (such as the film 80 shown in FIG. 5). The patterned dry film may expose, for example, an upper surface of the soldering pad 30. The resulted film 80, together with the recess 70S of the piezoelectric substrate may define a cavity to accommodate a plurality of transducers 10. For example, the dry film may be patterned by a photolithography process. The material for the film 80 may include a photosensitive polymer dry film.

In some embodiments, the fabrication method 300 may further include Step S34-1. A photoresist layer may be formed on the film 80, and then may be patterned to form a patterned photoresist layer PR. The patterned photoresist layer PR may also expose, for example, the upper surface of the soldering pad 30. For example, the photoresist layer may be patterned by a photolithography process. The material for the photoresist layer may include, for example, a positive photoresist or a negative photoresist. Taking a positive photoresist as an example, the photoresist located on the soldering pad 30 may be removed with irradiation (for example, ultraviolet light, deep ultraviolet light, electron beam, ion beam or X-ray irradiation), so as to expose the upper surface of the soldering pad 30.

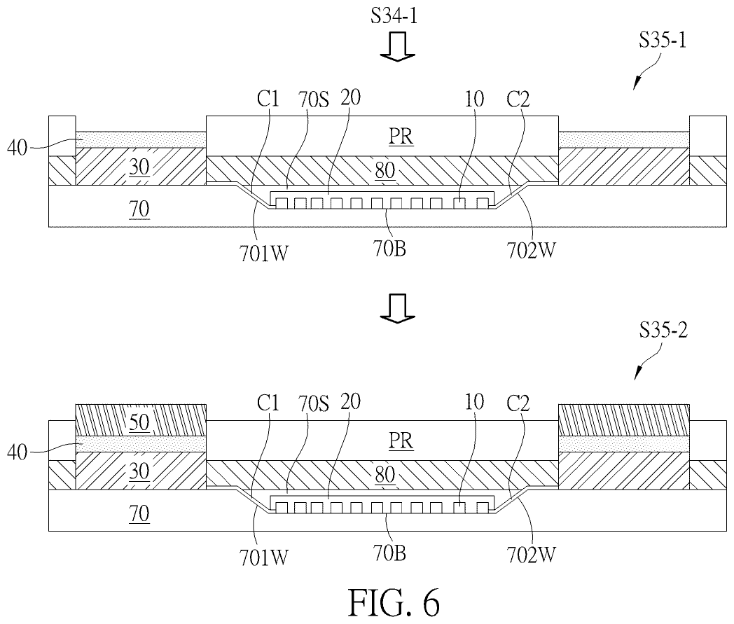

As shown in FIG. 6, the fabrication method 300 may further include Step S35-1 and Step S35-2. In Step S35-1, a seed layer 40 may be formed on the upper surface of the soldering pad 30. The seed layer 40 may provide a favorable surface for the subsequently formed metal layer 50 and may also be used to achieve an increased thickness. In some embodiments, the seed layer 40 may be formed by, for example, an electroless plating deposition process, and may provide sufficient conductivity for subsequent plating processes. In Step S35-2, a metal layer 50 may be formed on the seed layer 40. The metal layer 50 may be formed by evaporation, sputtering, electroplating or electroless plating, for example. In some embodiments, the seed layer 40 (Step S35-1) may be omitted and the metal layer 50 may be directly formed on the soldering pad 30. In Step S35-1 of forming the seed layer 40 or in Step S35-2 of forming the metal layer 50, the patterned photoresist layer PR may cover the film 80 and thus the film 80 may be protected during the fabrication process.

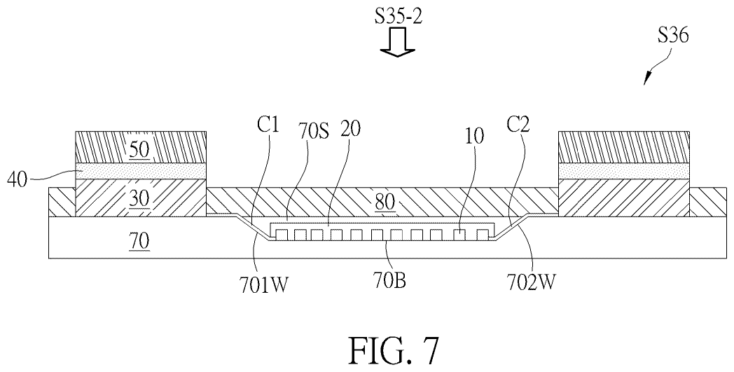

As shown in FIG. 7, the fabrication method 300 may further include Step S36. The patterned photoresist layer PR is stripped off. In some embodiments, a high-pressure stripping machine may be used to perform a strip off/lift off process to remove the patterned photoresist layer PR. A high-pressure stripping machine may include a processing tank, an ultrasonic apparatus and a high-pressure spraying apparatus. For example, the piezoelectric substrate 70 (and various layers thereon) may be placed in the processing tank, vibrated by the ultrasonic apparatus, and sprayed with a solvent by a high-pressure spraying apparatus to remove the patterned photoresist layer PR. This embodiment is only for illustration and is not intended to limit the present invention. In other embodiments, Step S36 may also be performed by other types of stripping machines.

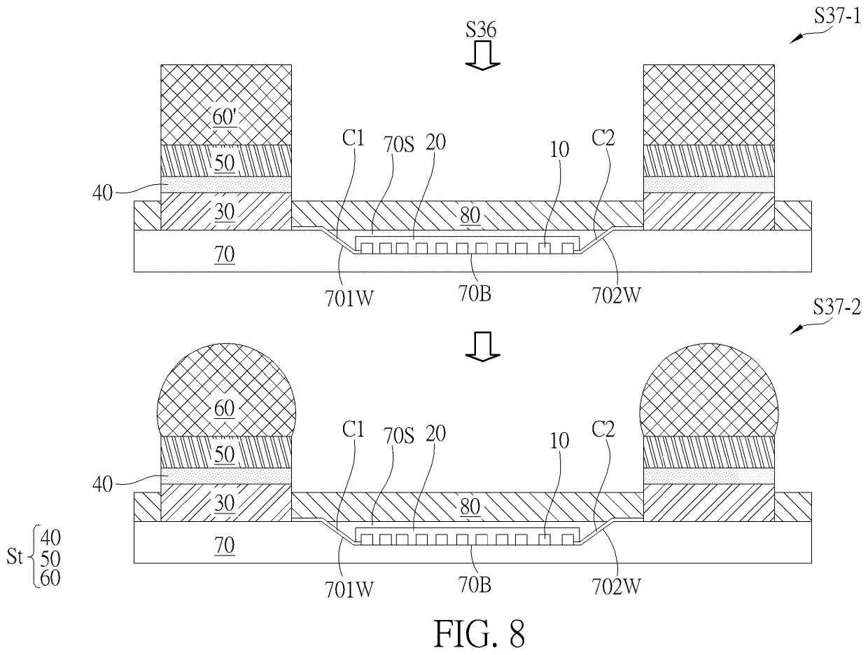

As shown in FIG. 8, the fabrication method 300 may further include Step S37-1 and Step S37-2. In Step S37-1, a screen printing step may be performed to form a solder joint 60′ on the metal layer 50. The screen printing step may include printing solder paste. In Step S37-2, the solder joints 60′ are reflowed to form a solder ball 60. The solder ball 60 may be a metal tin (Sn) ball, for example.

Referring back to FIG. 1, the fabrication method 300 may also include using a flip-chip technology to connect the device shown in FIG. 8 to a carrier 90. The solder balls 60 may serve as supports and/or electrical connections with the carrier 90, and the plurality of transducers 10 may face the carrier 90. Furthermore, a protective film 95 may be additionally disposed and it may cover on another surface of the piezoelectric substrate 70, which may be different from the substrate surface 71. The protective film 95 may also cover on the carrier 90. The material for the protective film 95 may include a photosensitive polymer dry film, such as a polyimide film or an epoxy film.

As shown in FIG. 1, the fabrication method 300 may also include applying a seal 96. In some embodiments, a compression molding process may be performed for better airtightness. For example, the compression molding process may be performed at a pressure of 0.5 to 5 megapascals (Mpa). Compared with the 8 to 9 Mpa pressure used in the conventional transfer molding, the pressure used in the compression molding process may be low, which may reduce the risk of squeezing or damaging the transducer 10, thereby increasing the yield of the acoustic wave device 1. The material for the seal 96 may include, for example, resin.

Those skilled in the art may readily observe that numerous modifications and alterations of the device and method may be made while retaining the teachings of the invention. Accordingly, the above disclosure should be construed as limited only by the metes and bounds of the appended claims.

What is claimed is:

1. An acoustic wave device comprising:
a piezoelectric substrate having a recess;
a plurality of transducers positioned in the recess, wherein
at least one of the plurality of transducers comprises:
a first bus bar disposed in parallel to a first direction;
a plurality of first electrodes extended in parallel to a second direction from the first bus bar;
a second bus bar disposed in parallel to the first direction; and
a plurality of second electrodes extended in parallel to the second direction from the second bus bar; and
a film covering the recess of the piezoelectric substrate.

2. The acoustic wave device of claim 1, wherein the piezoelectric substrate further comprises a substrate surface, the recess is recessed from the substrate surface, the recess includes a bottom and at least one side wall surrounding the bottom, and an obtuse angle is formed between one of the at least one side wall and the bottom.

3. The acoustic wave device of claim 2, further comprising a first connection part and a second connection part, wherein:
the plurality of transducers comprise a first transducer and a second transducer;
the first connection part is coupled to the first transducer, and the second connection part is coupled to the second transducer;
at least a portion of the first connection part is disposed on the at least one side wall of the recess; and
at least a portion of the second connection part is disposed on the at least one side wall of the recess.

4. The acoustic wave device of claim 3, further comprising a soldering pad disposed on the substrate surface of the piezoelectric substrate, and the soldering pad electrically connected to at least one of the plurality of transducers via the first connection part or the second connection part.

5. The acoustic wave device of claim 4, further comprising a stack disposed on the soldering pad.

6. The acoustic wave device of claim 5, wherein the stack includes a metal layer and a solder ball stacked in sequence.

7. The acoustic wave device of claim 2, wherein:
at least a portion of the first bus bar is disposed on the at least one side wall; or
at least a portion of the second bus bar is disposed on the at least one side wall.

8. The acoustic wave device of claim 1, further comprising a passivation layer disposed in the recess and covering the plurality of transducers.

9. The acoustic wave device of claim 1, wherein the film and the recess of the piezoelectric substrate define a cavity, and the plurality of transducers are disposed in the cavity.

10. The acoustic wave device of claim 1, wherein at least two of the plurality of transducers are electrically connected.

11. A fabrication method of an acoustic wave device comprising:
providing a piezoelectric substrate;
forming a recess in the piezoelectric substrate;
forming a plurality of transducers in the recess; and
forming a film covering the recess of the piezoelectric substrate.

12. The method of claim 11, wherein the recess is formed in the piezoelectric substrate by an etching process, the recess includes a bottom and at least one side wall surrounding the bottom, and an obtuse angle is formed between one of the at least one side wall and the bottom.

13. The method of claim 11, wherein:
the plurality of transducers comprise a first transducer and a second transducer;
the fabrication method of the acoustic wave device further comprises:
forming a first connection part on the at least one side wall of the recess; and
forming a second connection part on the at least one side wall of the recess; and
the first connection part is coupled to the first transducer, and the second connection part is coupled to the second transducer.

14. The method of claim 13, further comprising forming a soldering pad on the piezoelectric substrate, the soldering pad being electrically connected to at least one of the plurality of transducers via the first connection part or the second connection part.

15. The method of claim 14, wherein forming the film comprises:
forming a dry film on the piezoelectric substrate; and
patterning the dry film to form a patterned dry film, the patterned dry film exposing the soldering pad.

16. The method of claim 15, wherein the film and the recess of the piezoelectric substrate define a cavity, and the plurality of transducers are disposed in the cavity.

17. The method of claim 15, further comprising:
forming a photoresist layer on the patterned dry film; and
patterning the photoresist layer to form a patterned photoresist layer, the patterned photoresist layer exposing the soldering pad.

18. The method of claim 17, further comprising:
forming a seed layer and a metal layer on the soldering pad;
stripping off the patterned photoresist layer; and
forming a solder ball on the metal layer, and the step of forming the solder ball include a screen printing step and a reflow step.

19. The method of claim 11, further comprising forming a passivation layer, wherein the passivation layer is disposed in the recess and covering the plurality of transducers.

20. The method of claim 11, further comprising:
mounting the acoustic wave device on a carrier by compression molding, wherein the plurality of transducers face the carrier.
